(19) United States
(12) Patent Application Publication
(10) Pub. No.: US 2009/0033353 A1
(43) Pub. Date: Feb. 5, 2009

(54) SYSTEMS AND METHODS FOR ELECTRICAL CHARACTERIZATION OF INTER-LAYER ALIGNMENT

(75) Inventors: Kaung Shia Yu, San Jose, CA (US); Franz Xaver Zach, Los Gatos, CA (US)

Correspondence Address: MURABITO, HAO & BARNES, LLP, TWO NORTH MARKET STREET, THIRD FLOOR, SAN JOSE, CA, 95113, US

(73) Assignee: PDF SOLUTIONS, San Jose, CA (US)

(21) Appl. No.: 12/183,418

(22) Filed: Jul. 31, 2008

Related U.S. Application Data
(60) Provisional application No. 60/962,815, filed on Jul. 31, 2007.

(51) Int. Cl. G01R 31/26; G06F 17/50; G03F 1/00; H01L 23/52

(52) U.S. Cl. 324/765; 716/5; 430/5; 257/786; 257/E23.141

(57) ABSTRACT

Systems and methods for electrical characterization of inter-layer alignment. In one embodiment, a wafer including a plurality of test structures are accessed. The plurality of test structures include chains of conductive segments on multiple layers, coupled by vias. The plurality of test structures are designed with varying amounts of intentional misalignment between the multiple layers. The reactance of each of the plurality of test structures is measured. The reactance is analyzed to determine the process-induced inter-layer misalignment of the integrated circuit wafer.

### RELATED APPLICATION

This application claims benefit to U.S. Provisional Application 60/962,815, attorney docket PDFS-0068.PRO, filed Jul. 31, 2007, entitled “SYSTEMS AND METHODS FOR ELECTRICAL CHARACTERIZATION OF INTER-LAYER ALIGNMENT” to Yu and Zach, which is hereby incorporated herein by reference in its entirety.

### FIELD OF INVENTION

Embodiments in accordance with the present invention relate to the field of multi-layer photolithographic manufacturing. More specifically, embodiments of the present invention pertain to systems and methods for electrical characterization of inter-layer alignment.

### BACKGROUND

Multi-layer photolithographic manufacturing, e.g., as used in the production of integrated circuits, magnetic recording heads and the like, generally requires very precise alignment among structures that may span multiple layers. Existing optical measurement techniques, using optical alignment marks on multiple layers, generally require that a partially completed wafer be removed from a manufacturing process to make an alignment measurement, detrimentally reducing manufacturing throughput. Consequently, such measurements are typically only made on a sample basis. Unfortunately, such sampling produces only limited information on alignment, and limits the corrective actions available to improve the manufacturing process.

### SUMMARY OF THE INVENTION

Therefore, a need exists for systems and methods for electrical characterization of inter-layer alignment. A need also exists for systems and methods for electrical characterization of inter-layer alignment that may be applied to every wafer, imaging field and/or die produced, that also satisfies the above need. A further need exists for systems and methods for electrical characterization of inter-layer alignment that are compatible and complementary with existing systems and methods of multi-layer photolithographic manufacturing and test. Embodiments in accordance with the present invention provide for these needs.

Embodiments in accordance with the present invention utilize novel test structures to electrically characterize multi-layer alignment.

Accordingly, systems and methods for determining process-induced inter-layer misalignment of an integrated circuit wafer are disclosed.

In one embodiment, a wafer including a plurality of test structures is accessed. The plurality of test structures include chains of conductive segments on multiple layers, coupled by vias. The plurality of test structures are designed with varying amounts of intentional misalignment between the multiple layers and the vias. The reactance of each of the plurality of test structures is measured. The reactance values are analyzed to determine the process-induced inter-layer misalignment of the integrated circuit wafer.

In accordance with another embodiment of the present invention, a method of improving the inter-layer alignment of a semiconductor manufacturing process is disclosed. A method embodiment includes designing a set of design features including a line pattern on a first layer, a line pattern on a second layer and a contact pattern coupling the line patterns on the first and second layers. The design features include predetermined misalignment of the contact pattern relative to at least one of the line patterns. The design features are converted to physical structures utilizing the semiconductor manufacturing process. The electrical resistivity of the physical structures is measured. The electrical resistivity is analyzed as a function of the predetermined misalignment. A misalignment value is determined from the analyzing. A correction is applied to the semiconductor manufacturing process based on the misalignment value.

### BRIEF DESCRIPTION OF THE DRAWINGS

The accompanying drawings, which are incorporated in and form a part of this specification, illustrate embodiments of the invention and, together with the description, serve to explain the principles of the invention. Unless otherwise noted, the drawings are not to scale.

FIG. 1A illustrates a side sectional view of a portion of novel test structure, in accordance with embodiments of the present invention.

FIG. 1B illustrates in plan view the same portion of novel test structure as illustrated in FIG. 1A, in accordance with embodiments of the present invention.

FIG. 2 illustrates a plan view of a portion of novel test structure, in accordance with embodiments of the present invention.

FIG. 3 illustrates a plot of resistance verses intentional or “drawn” misalignment for a perfectly executed manufacturing process without any process misalignment, in accordance with embodiments of the present invention.

FIG. 4 illustrates a plot of resistance verses intentional or “drawn” misalignment for an exemplary realistic manufacturing process, in accordance with embodiments of the present invention.

FIG. 5 is a flow chart illustrating an exemplary method of electrical characterization of inter-layer alignment, in accordance with embodiments of the present invention.

FIG. 6 illustrates an exemplary result of an analysis of process-induced inter-layer misalignment for a plurality of dice on a wafer, in accordance with embodiments of the present invention.

FIG. 7 illustrates an exemplary wafer with exemplary fields, test structures and coordinate axes indicated, in accordance with embodiments of the present invention.

FIG. 8 illustrates several expressions and/or relations utilized in describing and analyzing inter-layer misalignment, in accordance with embodiments of the present invention.

### DETAILED DESCRIPTION

Reference will now be made in detail to various embodiments of the invention, examples of which are illustrated in the accompanying drawings. While the invention will be described in conjunction with these embodiments, it is understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the invention, numerous specific details are set forth in order to provide a thorough understanding of the invention. However, it will be recognized by one of ordinary skill in the art that the invention may be practiced without these specific details. In other instances, well known methods, procedures, components, and circuits have not been described in detail as not to unnecessarily obscure aspects of the invention.

### Notation and Nomenclature

Some portions of the detailed descriptions that follow (e.g., process 500) are presented in terms of procedures, steps, logic blocks, processing, and other symbolic representations of operations on data bits that can be performed on computer memory. These descriptions and representations are the means used by those skilled in the data processing arts to most effectively convey the substance of their work to others skilled in the art, A procedure, computer executed step, logic block, process, etc., is here, and generally, conceived to be a self-consistent sequence of steps or instructions leading to a desired result. The steps are those requiring physical manipulations of physical quantities. Usually, though not necessarily, these quantities take the form of electrical or magnetic signals capable of being stored, transferred, combined, compared, and otherwise manipulated in a computer system. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussions, it is appreciated that throughout the present invention, discussions utilizing terms such as “measuring” or “determining” or “accessing” or “analyzing” or “generating” or “performing” or “querying” or “sending” or “accessing” or “commanding” or “storing” or “dividing” or “computing” or “testing” or “calculating” or “determining” or “measuring” or “adjusting” or “comparing” or “synchronizing” or “retrieving” or “conveying” or “resuming” or “installing” or “gathering” or the like, refer to the action and processes of a computer system, or similar electronic computing device” that manipulates and transforms data represented as physical (electronic) quantities within the computer system's registers and memories into other data similarly represented as physical quantities within the computer system memories or registers or other such information storage, transmission or display devices.

### Systems and Methods for Electrical Characterization of Inter-Layer Alignment

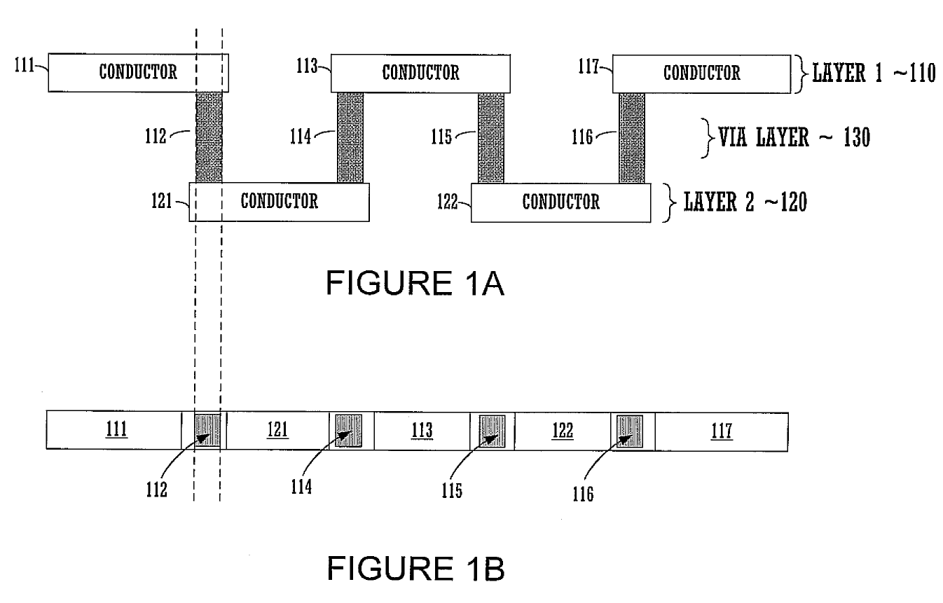

FIG. 1A illustrates a side sectional view of a portion of novel test structure 100, in accordance with embodiments of the present invention. Test structure 100 may be described as a “chain.” Test structure 100 is an integrated circuit and is generally composed of conductive segments, which may be metal, at two different layers coupled by vias through a dielectric, or other intervening layers, in a repetitive manner.

As illustrated in FIG. 1A, test structure 100 comprises a first conductive segment 111 disposed in layer 110. Test structure 100 further comprises a second conductive segment 121 disposed in layer 120. Similarly, test structure 100 comprises conductive segments 113 and 117 in layer 110, and conductive segment 122 in layer 120. It is appreciated that an actual test structure may generally comprise more than the illustrated five conductive segments. For example, a typical test structure may comprise from a few thousand to hundreds of thousands or even a few million of conductive segments.

First conductive segment 111 is electrically coupled to second conductive segment 121 by via 112. Similarly, second conductive segment 121 is electrically coupled to conductive segment 113 by via 114, and conductive segment 113 is electrically coupled to conductive segment 122 by via 115. Likewise, conductive segment 122 is electrically coupled to the last conductive segment 117 by via 116. Vias 112, 114, 115 and 116 are typically formed in a via or contact layer 130, also known as a dielectric layer. The via holes are generally filled with a conducting material. In this manner, the first conductive segment 111 is electrically coupled to the last conductive segment 117.

FIG. 1B illustrates in plan view the same portion of novel test structure 100 as illustrated in FIG. 1A, in accordance with embodiments of the present invention. It is to be appreciated that FIG. 1B illustrates ideal, or perfect alignment of the structures 111, 112, 113, 114, 115, 116, 117, 121 and 122. For example, first conductive segment 111 is perfectly aligned with second conductive segment 121, and via 112 is perfectly aligned with both first conductive segment 111 and second conductive segment 121 through via layer 130.

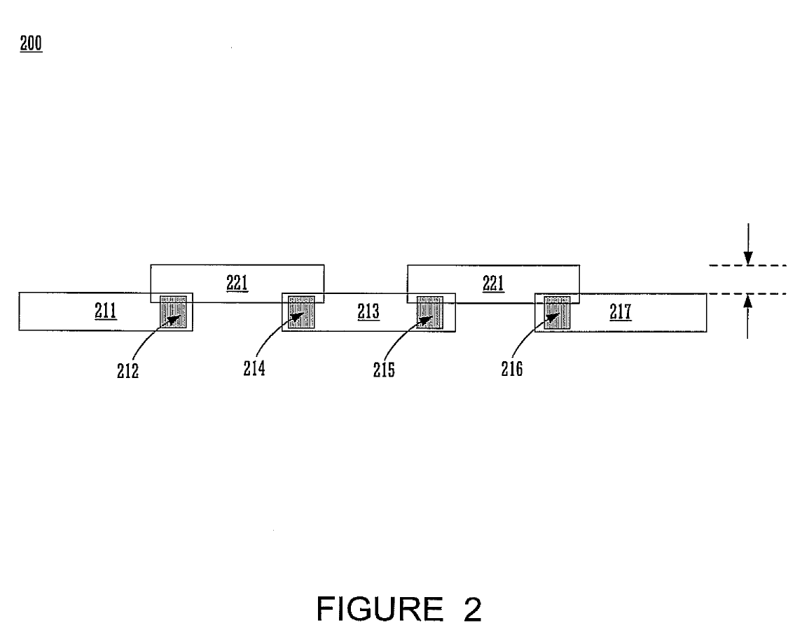

FIG. 2 illustrates a plan view of a portion of novel test structure 200, in accordance with embodiments of the present invention. Test structure 200 comprises similar elements to those of test structure 100, as illustrated in FIG. 1B. Test structure 200 comprises conductive segments 211, 213 and 217 on one layer, conductive segments 221 and 222 on a second layer. Conductive segments on one layer are electrically coupled to conductive segments on the second layer by vias 212, 214, 215 and 216.

In contrast to test structure 100, as illustrated in FIG. 1B, however, test structure 200 is intentionally misaligned. For example, conductive segment 221 is not completely aligned with conductive segment 211 and/or via 212. Further, conductive segment 221 only overlaps a portion of via 212. As illustrated in FIG. 2, the segments (221, 222) of layer 2 are offset relative to the segments (211, 213, 217) of layer 1 and to the vias (212, 214, 215, 216) in a direction perpendicular to the direction of current flow. In a similar manner, the segments of layer 2 may be offset relative to the segments of layer land the vias. Embodiments in accordance with the present invention are well suited to, and may generally utilize, offsets of both directions.

It is to be appreciated that test structure 200 is designed with intentional misalignment between vias and a conductive layer, e.g., the misalignment s is part of the design, and may be reflected in a design database and/or set of masks. For example, even with perfect or ideal alignment of masks in a manufacturing process, an embodiment of test structure 200 would still exhibit misalignment.

It is appreciated that such intentional misalignment is generally a violation of design rules, and generally cannot be created by conventional design tools and techniques. Thus, the creation of test structures, such as test structure 200, may require modification of a design system to overcome design rules limitations and checking, or require special approval from representatives of the fabrication facility.

It is to be appreciated that a typical manufacturing process will generally introduce some inter-layer misalignment. Thus, a perfectly aligned (by design) multi-layer structure, such as test structure 100 of FIG. 1A, may comprise some offset due to manufacturing processes when actually rendered, e.g., in an integrated circuit. Similarly, a structure with intentional misalignment, such as test structure 200 of FIG. 2, may comprise a second component of offset due to a manufacturing processes when actually rendered, e.g., in an integrated circuit.

Test structures 100 (FIG. 1A) and/or 200 (FIG. 2) are typically represented in a design database, e.g., stored on computer usable media for use with a computer aided design (CAD) tool, or in several photolithographic masks, for use in manufacturing a device, e.g., an integrated circuit, via a photolithographic manufacturing process. In the exemplary case of an integrated circuit, such test structures may be embedded into a design with other functional circuitry. These chain-type multi-layer structures are common to typical semiconductor products, e.g., as wiring to interconnect various devices. During manufacturing, sequential steps are used to form such structures. Since there may be at least three masks involved in forming such structures, any misalignment between layers will cause the final structure to deviate slightly from its intended position (known as misalignment, inter-layer misalignment, or overlay error). When such deviations reach a critical extent, an electrical property (e.g., the total resistance) will generally change as a result of loss in hole coverage. Such misalignment also increases a likelihood that this and similar structures will not function e.g., they fail.

It is to be appreciated that a chain of coupled conductive segments such as test structure 100 (FIG. 1A) will exhibit a characteristic impedance, including both imaginary and real components. The characteristic impedance of such a chain will be influenced by a number of factors, including, for example, the number, width and total length of conductive segments, the number and geometry, e.g., length and diameter, of vias and the like.

Another attribute of such a chain that influences characteristic impedance is its inter-layer alignment. For example, an offset or misalignment between conductive segments on different layers may influence both real and imaginary components of characteristic impedance. Further, misalignments between conductive segments and vias on one or more layers may generally increase resistance of such a chain. For example, as a smaller portion of a via connects with a conductive segment due to misalignment, the impedance of such a connection is generally increased.

Advantageously, utilizing product-like features such as test structure 100 (FIG. 1A) and/or 200 FIG. 2 will generally produce superior indications of misalignment, in comparison to the conventional art. For example, conventional misalignment metrology structures, e.g., optical alignment structures, are generally large relative to the wavelength of the light used to image them, and other features. Embodiments in accordance with the present invention utilize metrology structures with relatively smaller features, such as those used in semiconductor circuitry. Thus, embodiments in accordance with the present invention may be able to advantageously detect and/or identify misalignment caused by certain types of lens aberrations, for example Coma aberrations, which are not detected accurately by conventional art methods.

Embodiments in accordance with the present invention place a plurality of test structures comprising multi-layer chains of conductive segments into an integrated circuit design database. The plurality of test structures comprise varying amounts of intentional, e.g., by design, misalignment between the segments of different layers. The test structures have varying amounts of misalignment in both directions.

For example, in one embodiment, eleven test structures of multi-layer chains of conductive segments are designed. One test structure is designed with zero or no intentional misalignment. A first complimentary pair of test structures is designed with +/−10% misalignment. It is appreciated that the notation “+/−” refers to misalignment in opposite directions. Thus, in the exemplary +/−10% pair of test structures, one chain has an intentional or designed misalignment of 10% between conductive segments of one layer relative to the via layer, and the other chain has the same magnitude of misalignment in the opposite direction. A second complimentary pair of test structures is designed with +/−20% misalignment. A third complimentary pair of test structures is designed with +/−40% misalignment. A fourth complimentary pair of test structures is designed with +/−60% misalignment. A fifth complimentary pair of test structures is designed with +1-80% misalignment.

It is appreciated that, when rendered, the misalignment of the exemplary 11 test structures will, in general, be different from the design misalignment, by virtue of misalignment introduced by the manufacturing process. In general, some rendered test structures will have improved misalignment, e.g., they are less misaligned that they were designed to be, and some rendered test structures will have worse misalignment, e.g., they are more misaligned that they were designed to be.

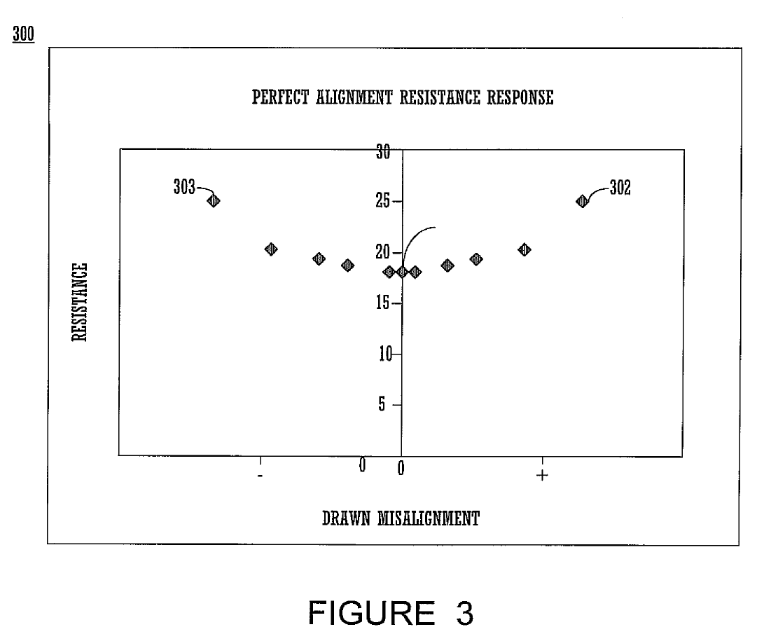

FIG. 3 illustrates a plot 300 of resistance verses intentional, predetermined or “drawn” misalignment for a perfectly executed manufacturing process without any process misalignment, in accordance with embodiments of the present invention. In general, resistance increases with increasing amounts of intentional misalignment. For example, point 301 corresponds to a test structure, e.g., test structure 100 (FIG. 1A) with zero drawn misalignment, and shows the least amount of resistance. Point 302 corresponds to a test structure with a relatively large amount of intentional or drawn misalignment, e.g., test structure 200 (FIG. 2). Point 302 indicates a higher amount of resistance than point 301. Similarly, point 303, with the same magnitude of intentional or drawn misalignment as point 302, but in the opposite direction, shows a similar magnitude of resistant to point 302. It is appreciated that plot 300 is symmetric about the point of lowest resistance, corresponding to best alignment.

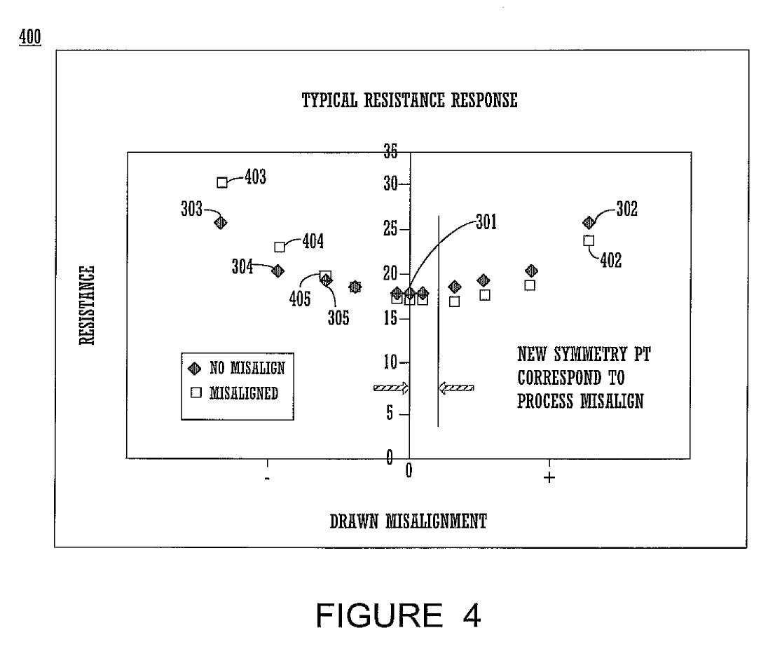

FIG. 4 illustrates a plot 400 of resistance verses “drawn” misalignment for an exemplary realistic manufacturing process, in accordance with embodiments of the present invention. The exemplary realistic manufacturing process introduces a finite amount of process-induced inter-layer misalignment, or overlay error. The “theoretical ideal” points of plot 300 are also included in plot 400, for comparison. After a normal manufacturing process that renders a plurality of test structures, a resistance measurement is taken for each test structure chain, e.g., from one end to the other end. The resistance measurements may be represented as in plot 400.

It is appreciated that points 403, 404 and 405 have greater resistance than their corresponding “ideal” points, e.g., points 303, 304 and 305. This change in resistance indicates that the corresponding rendered test structures have more inter-layer misalignment than the designed inter-layer misalignment for that particular test structure. Such differences between the designed inter-layer misalignment and the actual inter-layer misalignment are due to an imperfect manufacturing process.

Similarly, the points of plot 400 to the right of point 405, e.g., point 402, have less resistance than their corresponding “ideal” points, e.g., point 302. This change in resistance indicates that the corresponding rendered test structures have less inter-layer misalignment than the designed inter-layer misalignment for that particular test structure. Such differences between the designed inter-layer misalignment and the actual inter-layer misalignment are due to the same imperfect manufacturing process that causes points 403, 404, 405 to show increased resistance.

It is appreciated that the typical misalignment of plot 400 retains an axis of symmetry about a point of least resistance. Due to the process misalignment or overlay error, however, such axis of symmetry may no longer be at zero drawn misalignment. In general, an axis of symmetry occurs at a point at which the combination of intentional or drawn misalignment combines with process misalignment to produce an actual, rendered structure with little or no misalignment.

By determining an axis of symmetry from resistance measurements of a plurality of rendered test structures comprising intentional and process-induced misalignment, the process-induced misalignment may be determined, in accordance with embodiments of the present invention. Advantageously, such determination of process-induced misalignment may be utilized to correct the manufacturing process in order to reduce process-induced inter-layer misalignment, and beneficially improve process yield.

It is appreciated that process-induced inter-layer misalignment generally occurs, and is usually analyzed, in the plan view of a multi-layer structure, e.g., viewed from the top of a semiconductor wafer. Embodiments in accordance with the present invention are well suited to, and may generally utilize, pluralities of test structures in both the horizontal and vertical directions in order to determine both horizontal and vertical components, e.g., orthogonal components, of process-induced inter-layer misalignment. For example, a wafer may comprise a first set of 11 test structures of varying intentional misalignment in a first dimension, and a second set of 11 test structures of varying intentional misalignment in a second dimension, perpendicular to the first dimension. The test structures should generally be parallel to edges of individual die; however that is not required.

In accordance with embodiments of the present invention, test structures may be designed and rendered per die, per field (an imaging unit comprising multiple dice) and/or at the wafer level. Multiple sets of such structures may be implemented, each targeting a different layer or combination of layers, e.g., contact layer to poly layer, contact layer to active layer, metal 1 layer to contact layer, voltage 1 layer to metal 1 layer, etc.).

Test structures may further be designed and/or rendered in functional or nonfunctional areas of an integrated circuit. For example, test structures may be designed and formed in areas generally reserved for cutting a wafer into individual die, e.g., “scribe lines.” For example, resistance measurements may be made on test structures prior to cutting a wafer into individual die. In this manner, valuable integrated circuit functional real estate is not consumed by the test structures. Advantageously, process misalignment of the actual manufacturing process may be monitored without decreasing the integrated circuit real estate available for functional elements.

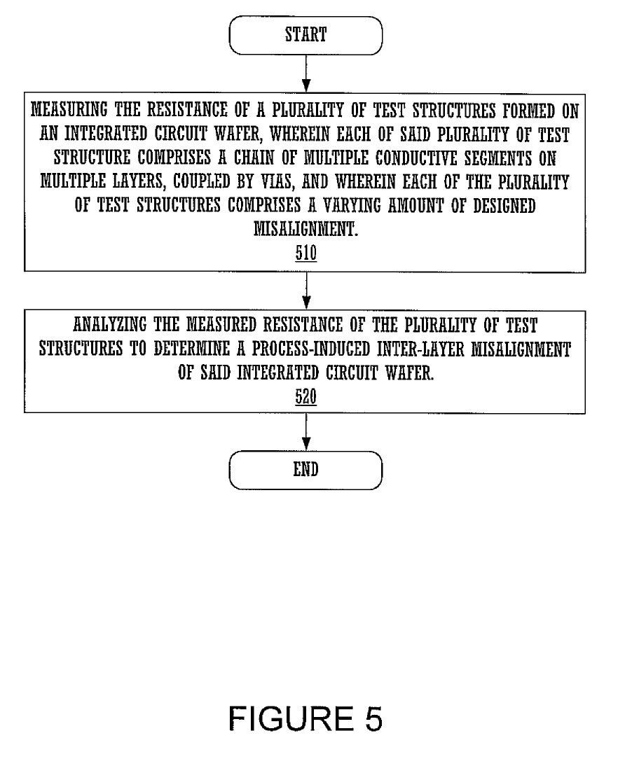

FIG. 5 is a flow chart illustrating an exemplary method 500 of electrical characterization of inter-layer alignment, in accordance with embodiments of the present invention. In 510, the resistance of a plurality of test structures is measured. The test structures comprise a chain of multiple conductive segments on multiple layers, coupled by vias. Each of the plurality of test structures comprises a varying amount of designed misalignment.

In 520, the resistance measurements of the plurality of test structures are analyzed to determine a process-induced inter-layer misalignment. The analysis procedure may include a numerical regression engine in which a linear combination of symmetrical basis function is used to represent the expected resistance response. The function is made to shift laterally until it can best describe the measured resistance response curve. The symmetry point of that function is the process misalignment amount. This procedure may be repeated for both orientations, all layers, all fields, all wafers to gain a comprehensive view of the process overlay capability.

In accordance with embodiments of the present invention, the process misalignment need not be rounded to the nearest drawn misalignment amount. A role of the deliberately misaligned structures is to provide enough sampling point of the entire resistance curve to provide information to determine process misalignment to a desired precision. The plurality of test structure does not need to be very dense. It is appreciated that the plurality of test structures does not have to be drawn symmetrically.

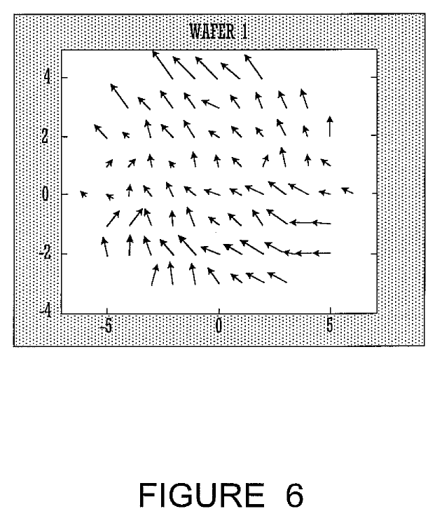

FIG. 6 illustrates an exemplary result 600 of an analysis of process-induced inter-layer misalignment for a plurality of dice on a wafer, for example, as a result of process 500, in accordance with embodiments of the present invention. The axes identify individual die on the wafer relative to the center of the wafer at 0,0. Each vector of result 600 illustrates a magnitude and direction of process-induced inter-layer misalignment for a corresponding die on the wafer.

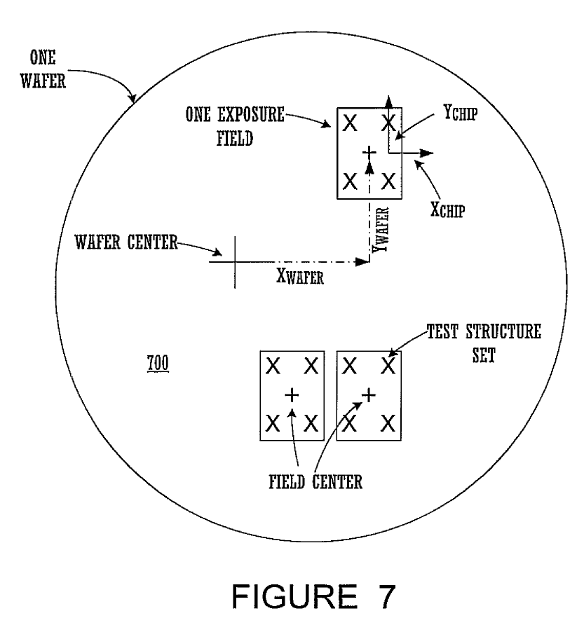

FIG. 7 illustrates an exemplary wafer 700 with exemplary fields and test structures, in accordance with embodiments of the present invention. FIG. 7 further identifies coordinate axes for Xchip, Ychip, Xwafer and Ywafer, as used in the following discussion.

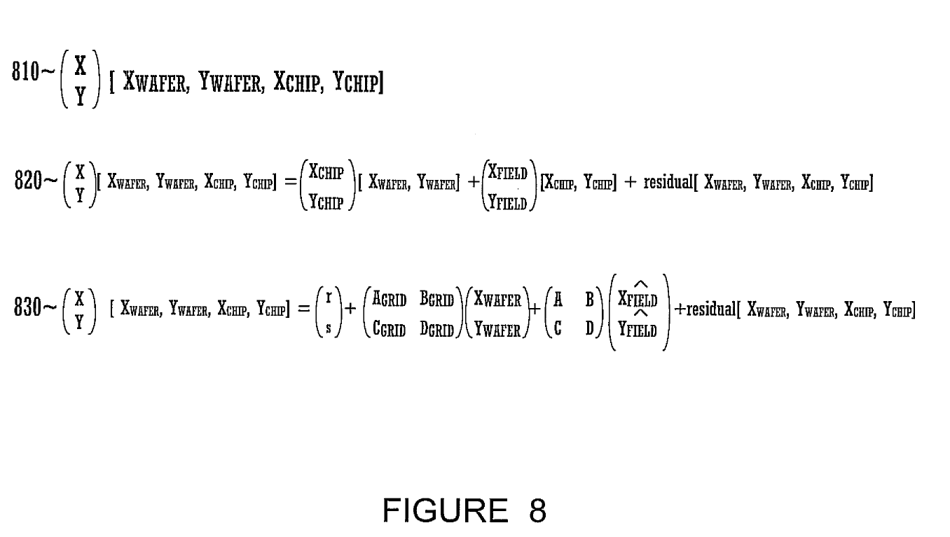

FIG. 8 illustrates several expressions and/or relations utilized in describing and analyzing inter-layer misalignment, in accordance with embodiments of the present invention.

In accordance with embodiments of the present invention, a misalignment value may be derived, representing a relative displacement of the one layer to another layer representative of the misalignment present in the vicinity of the structures. In one exemplary embodiment, four sets of misalignment test structures are placed, one each at the corner of each exposure field. Data are collected for a set of exposure fields on a wafer. For analysis purposes, the misalignment values x, y (representing the x, y components of the misalignment) are indexed using the location of the center of the exposure field on the wafer (coordinates Xwafer, Ywafer, as described in FIG. 7) and the distance of the measurement site from the center of the exposure field (coordinates Xchip, Ychip, as described in FIG. 7).

Expression 810 of FIG. 8 illustrates a formal expression of misalignment.

In a first portion of the analysis, for each exposure field, the average misalignment of the entire field, and the misalignment of the four corners of the field relative to the center may be extracted. The resulting data consist of a set of average misalignment vectors (one for each exposure field) and the misalignment of each one of the four corners relative to the displacement of the center of the field.

In a second portion of the analysis, these values are then described by a model, which describes the misalignment values as a function, e.g., as a continuous function, of the wafer coordinates. The dependencies on the wafer coordinates are separated into a dependency exclusively on wafer coordinates Xwafer, Y wafer and a dependency on within field coordinates Xchip, Ychip. This separation reflects the fact that different mechanisms cause misalignment on a wafer level vs. misalignment on a field level. Misalignment on a field level is primarily driven by the optical imaging part of the exposure tool, for example, magnification errors due to incorrectly set lens heating or reticule distortions whereas misalignment on a wafer level may be driven by issues in wafer stage metrology, wafer stage movement or wafer processing issues. It is appreciated that random metrology error is one of the sources that contributes to unexplained residual components. This relation is described by relation 820 of FIG. 8.

In a third portion of the analysis the dependency of misalignment on the wafer coordinates is assumed to be linear as described in relation 830 of FIG. 8.

The parameters r, s, A, B, C, D for the grid and a, b, c, d for the field terms are constant, independent of the respective wafer coordinates. In particular, this means that the parameters a, b, c and d describing the field components of the overlay model are independent of wafer coordinates Xwafer, Ywafer. This assumption is equivalent to the idea that the field portion of this misalignment model is effectively determined from the average (over all exposure fields) of the field misalignments. It is to be appreciated that all of the above parameters may vary from wafer to wafer, lot to lot, etc.

In one extension of the model, in accordance with embodiments of the present invention, the dependency on wafer coordinates may be enhanced to allow for higher order terms (e.g., higher order polynomials in coordinates). An example is to allow a dependency of the form Xwafer², Ywafer² and/or Xwafer multiplied by Ywafer, in addition to the linear components Xwafer, Ywafer. This more advanced analysis enables capturing more process issues than is commonly possible using a simpler model. As an example, this type of analysis has enabled the detection of chuck deformations on dual stage exposure systems.

In another extension of the methodology, in accordance with embodiments of the present invention, the within field components of the model are allowed to exhibit a dependency on the wafer coordinates. This extension has proven useful in assessing lens heating related issues.

Advantageously, this novel method and apparatus enables electrical measurement of process-induced inter-layer misalignment. Beneficially, such electrical measurements may be performed with very large throughput, for example using commercially available high speed, highly parallel electrical parametric testers, such as the pdFasTest™ parametric tester, commercially available from PDF Solutions, Inc., of San José, Calif. Further, such measurements may be made after a wafer has completed fabrication, in contrast to conventional art methods that generally must be performed between processing stages, e.g., interrupting process flow. As such, process-induced inter-layer misalignment may be determined for multiple layers of every wafer, field and/or die, resulting in a much better understanding of process-induced inter-layer misalignment than is available under the conventional art.

Also of advantage, the basic test structure is a chain, which is a common structures in integrated circuits. Further, because the chain test structure comprises large numbers of vias, resistance measurements are highly stable and are relatively insensitive to process variation. Even though there may be many thousand segments and vias, such test structures are relatively small, and have an advantageously small impact on usable integrated circuit real estate.

Embodiments in accordance with the present invention provide for systems and methods for systems and methods for electrical characterization of inter-layer alignment. Embodiments in accordance with the present invention provide also provide for a systems and methods for systems and methods for electrical characterization of inter-layer alignment that may be applied to every wafer, imaging field and/or die produced, Further, embodiments in accordance with the present invention provide for systems and methods for electrical characterization of inter-layer alignment that are compatible and complementary with existing systems and methods of multi-layer photolithographic manufacturing and test.

Various embodiments of the invention are thus described. While the present invention has been described in particular embodiments, it should be appreciated that the invention should not be construed as limited by such embodiments, but rather construed according to the below claims.

What is claimed is:

1. A method of determining process-induced inter-layer misalignment of an integrated circuit wafer comprising:
measuring a plurality of electrical parameters of a plurality of test structures of said integrated circuit wafer; and
determining said process-induced inter-layer misalignment of said integrated circuit wafer from said plurality of electrical parameters.

2. The method of claim 1 wherein said test structures comprise designed inter-layer misalignment.

3. The method of claim 2 wherein said plurality of test structures are characterized as having more than one amount of designed interlayer misalignment.

4. The method of claim 3 wherein said plurality of test structures comprise pairs of test structures characterized as having the same magnitude of designed inter-layer misalignment in different directions.

5. The method of claim 1 wherein said plurality of electrical parameters comprises resistance of at least one of said test structures.

6. The method of claim 1 wherein said plurality of electrical parameters comprises reactance of at least one of said test structures.

7. The method of claim 1 wherein said determining comprises finding a center point of rendered inter-layer misalignment of said plurality of test structures.

8. A method of determining process-induced inter-layer misalignment of an integrated circuit wafer comprising:
accessing a wafer comprising a plurality of test structures, wherein said plurality of test structures comprise chains of conductive segments on multiple layers, coupled by vias, and wherein said plurality of test structures are designed with varying amounts of predetermined misalignment between said multiple layers and said vias;
measuring the reactance of each of said plurality of test structures; and
analyzing said reactance to determine said process-induced inter-layer misalignment of said integrated circuit wafer.

9. The method of claim 8 wherein said measuring said reactance comprises measuring a direct current resistance.

10. The method of claim 8 wherein said measuring said reactance comprises measuring an alternating current capacitance.

11. The method of claim 8 wherein said measuring said reactance comprises measuring an alternating current inductance.

12. The method of claim 8 wherein said wafer comprises a plurality of die and wherein further each die of said wafer comprises said plurality of test structures.

13. The method of claim 8 wherein at least a portion of one of said plurality of test structures is rendered in a scribe line area of said wafer.

14. The method of claim 8 wherein each imaged field of said wafer comprises said plurality of test structures.

15. A method of improving the inter-layer alignment of a semiconductor manufacturing process comprising:
designing a set of design features comprising a line pattern on a first layer, a line pattern on a second layer and a contact pattern coupling said line patterns on said first and second layers;
wherein said design features comprise predetermined misalignment of said contact pattern relative to at least one of said line patterns;
converting said design features to physical structures utilizing said semiconductor manufacturing process;
measuring the electrical resistivity of said physical structures;
analyzing said electrical resistivity as a function of said predetermined misalignment;
determining a misalignment value from said analyzing; and
applying a correction to said semiconductor manufacturing process based on said misalignment value.

16. The method of claim 15 wherein said misalignment value is analyzed utilizing a model that describes the misalignment as a function of within-wafer and within-exposure field coordinates.

17. A computer usable media comprising:
a database of a design for a plurality of layers of a semiconductor wafer, wherein said design comprises:
a conductive line pattern for a first layer;
a conductive line pattern for a second layer;
a contact pattern for electrically coupling said line patterns of said first and second layers; and
wherein said design comprise predetermined misalignment of said contact pattern relative to at least one of said line patterns.

18. A mask set for use in photolithographic manufacturing of an integrated circuit comprising:
a plurality of masks for forming a conductive line pattern for a first layer;
a plurality of masks for forming a conductive line pattern for a second layer;
a plurality of masks for forming a contact pattern for electrically coupling said line patterns of said first and second layers; and
wherein said mask set comprises predetermined misalignment of said contact pattern relative to at least one of said line patterns.

19. A semiconductor wafer comprising:
a conductive line pattern on a first layer;
a conductive line pattern on a second layer;
a contact pattern for electrically coupling said line patterns of said first and second layers; and
wherein said contact pattern comprises predetermined misalignment relative to at least one of said line patterns.

20. The semiconductor wafer of claim 19 wherein process induced misalignment of said contact pattern relative to said at least one of said line patterns corrects said predetermined misalignment.
